(19) United States
(12) Patent Application Publication
(10) Pub. No.: US 2018/0294254 A1
(43) Pub. Date: Oct. 11, 2018

(54) MICRO LIGHT EMITTING DIODE DISPLAY PANEL AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventors: Lixuan CHEN, Shenzhen, Guangdong (CN); Dongze LI, Shenzhen, Guangdong (CN)

(73) Assignee: Shenzhen China Star Optoelectronics Technology Co., Ltd., Shenzhen, Guangdong (CN)

(21) Appl. No.: 15/526,330

(22) PCT Filed: Mar. 21, 2017
(86) PCT No.: PCT/CN2017/077589

§ 371 Date: May 11, 2017

(30) Foreign Application Priority Data
Jan. 24, 2017 (CN) 201710055160.X

(51) Int. Cl. H01L 25/075; G02B 19/00; H01L 33/60; H01L 33/62; H01L 33/40

(52) U.S. Cl. CPC H01L 25/0753; G02B 19/0019; G02B 19/0061; H01L 33/32; H01L 33/62; H01L 33/405; H01L 33/60

(57) ABSTRACT

Provided are a micro light emitting diode display panel and a manufacturing method thereof, and the display panel comprising a substrate and a plurality of micro light emitting diodes, and the substrate comprising a plurality of sub pixel regions arranged in array, and each of the sub pixels being provided with a groove, and an inner surface of the groove being covered with a first reflective electrode and a second reflective electrode which are insulated from each other, and each of the micro light emitting diodes being arranged in one of the grooves, and one pin of the micro light emitting diode being connected with the first reflective electrode and the other pin being connected with the second reflective electrode, and the first reflective electrode and the second reflective electrode reflect light emitted from the micro light emitting diode back to the groove.

### CROSS REFERENCE

This application claims the priority of Chinese Patent Application No. 201710055160.X, entitled “Micro light emitting diode display panel and manufacturing method thereof”, filed on Jan. 24, 2017, the disclosure of which is incorporated herein by reference in its entirety.

### FIELD OF THE INVENTION

The present invention relates to a display technology field, and more particularly to a micro light emitting diode display panel and a manufacturing method thereof.

### BACKGROUND OF THE INVENTION

The Micro LED display is a kind of display, in which the image display is realized by using a high density, small size LED array integrated on a substrate as a display pixel. Similar with the large size outdoor LED display screen, each pixel can be addressed and individually driven and lighted, the micro LED can be considered as a scaled-down version of the outdoor LED display screen to reduce the pixel dot distance from millimeter level to micron level. The Micro LED display is a self-luminous display as the same as the organic light emitting diode display (OLED). However, the pLED display possesses advantages of better material stability, longer life and no image imprinting in comparison with the OLED display, and is considered to be the biggest competitor of the OLED display.

In prior art, the size of the Micro LED is much smaller than the size of the existing pixel. For instance, in the present 55 inches FHD display, the length and the width of the sub pixels (R/G/B) may be 600 u and 200 um, respectively. The size of the Micro LED is about 10-50 um. It results in that the periphery of Micro LED in the sub pixel has a larger non display area. Because the light of the Micro LED is emitted in all directions, more light energy is lost in the non display direction, and the light utilization is lower.

### SUMMARY OF THE INVENTION

An objective of the present invention is to provide a micro light emitting diode display panel, which can promote the light utilization.

Another objective of the present invention is to provide a manufacturing method of a micro light emitting diode display panel, in which the micro light emitting diode display panel produced by the method can promote the light utilization.

For realizing the aforesaid objective, the technical solution provided by the embodiments of the present invention is:

the embodiment of the present invention provides a micro light emitting diode display panel, comprising a substrate and a plurality of micro light emitting diodes, and the substrate comprising a plurality of sub pixel regions arranged in array, and each of the sub pixels being provided with a groove, and an inner surface of the groove being covered with a first reflective electrode and a second reflective electrode which are insulated from each other, and each of the micro light emitting diodes being arranged in one of the grooves, and one pin of the micro light emitting diode being connected with the first reflective electrode and the other pin being connected with the second reflective electrode, and the first reflective electrode and the second reflective electrode reflect light emitted from the micro light emitting diode back to the groove.

The micro light emitting diode display panel further comprises a reflective layer, and the reflective layer is located under the groove, and the reflective layer reflects the light emitted from the micro light emitting diode back to the groove.

A boss is arranged at a bottom of the groove, and the boss separates the first reflective electrode and the second reflective electrode.

The micro light emitting diode is located on the boss, and the two pins of the micro light emitting diode are respectively located at two sides of the boss.

A material of the first reflective electrode and the second reflective electrode is aluminum or silver.

The plurality of micro light emitting diodes comprise red micro light emitting diodes, green micro light emitting diodes and blue micro light emitting diodes.

All of the plurality of micro light emitting diodes are GaN micro light emitting diodes, InGaN micro light emitting diodes and AlGaInP micro light emitting diodes.

The embodiment of the present invention further provides a manufacturing method of a micro light emitting diode display panel, comprising:

providing a substrate, and the substrate comprising a plurality of sub pixel regions arranged in array, and each of the sub pixels being provided with a groove;

forming a reflective electrode layer on the substrate, and the reflective electrode layer covering an inner surface of the groove;

forming a photoresist layer on the reflective electrode layer;

etching the reflective electrode layer through the photoresist layer to divide a portion of the reflective electrode layer at a bottom of the groove to form a first reflective electrode and a second reflective electrode;

locating a micro light emitting diode in the groove by a micro transfer printing method, wherein one pin of the micro light emitting diode is connected with the first reflective electrode and the other pin is connected with the second reflective electrode.

A sputtering method or a heat evaporation method is used to form the reflective electrode layer on the substrate.

The step of forming the reflective electrode layer on the substrate, and the reflective electrode layer covering the inner surface of the groove comprises coating polydiallyldimethylammonium chloride on a surface of the substrate, and coating negatively charged silver nanoparticles to form the reflective electrode layer.

The embodiments of the present invention have advantages or benefits:

In the micro light emitting diode display panel and the manufacturing method thereof according to the present invention, by arranging the groove on the substrate and covering the inner surface of the groove with the reflective electrode, and by connecting the reflective electrodes with the micro light emitting diode, the drive circuit on the substrate controls the micro light emitting diode to emit light. The light emitted from the micro light emitting diode can be reflected back to the groove with the reflective electrodes of the inner surface of the groove, and thereby, to reduce the loss of light energy and to improve light utilization.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structure diagram of a micro light emitting diode display panel according to one embodiment of the present invention.

FIG. 2 is a structure diagram of a micro light emitting diode display panel according to another embodiment of the present invention.

FIG. 3 is a flowchart diagram of a manufacturing method of a micro light emitting diode display panel according to the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

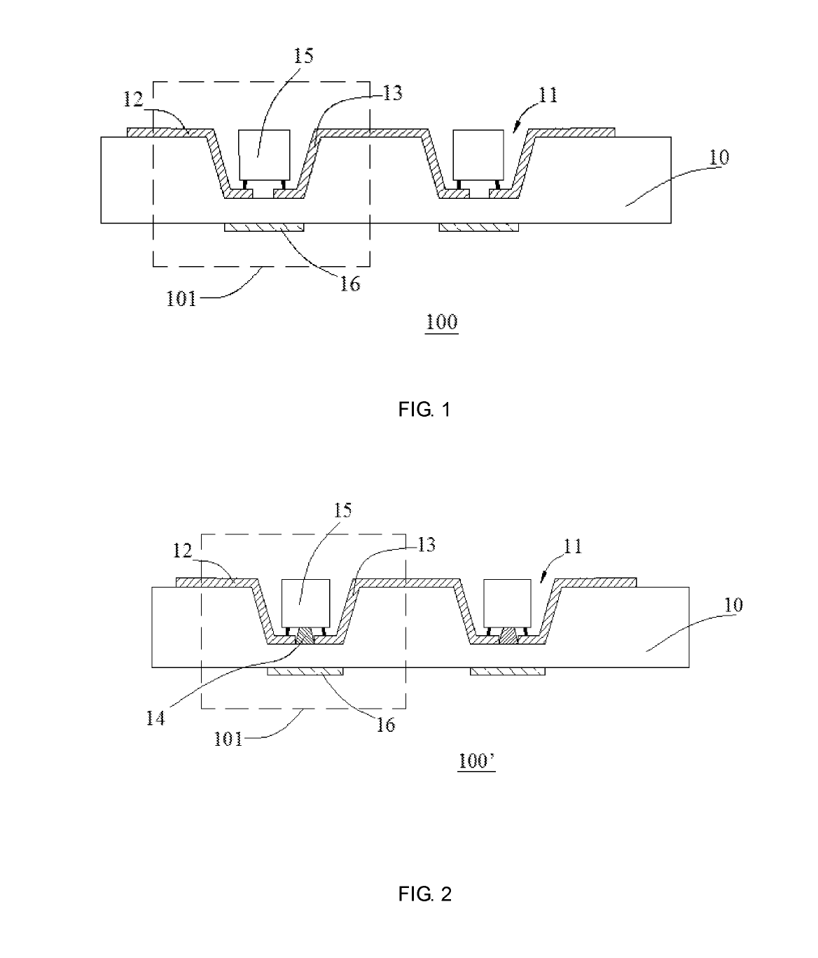

Please refer to FIG. 1. FIG. 1 is a structure diagram of a micro light emitting diode display panel according to one embodiment of the present invention. The micro light emitting diode display panel 100 provided by this embodiment comprises a substrate 10 and a plurality of micro light emitting diodes 15. The substrate 10 comprises a plurality of sub pixel regions (not shown in figure) arranged in array, and generally, each pixel region comprises three sub pixel regions 101 (i.e. the part that the dotted line surrounds). Each of the sub pixels 101 provided with a groove 11, and a projection of the groove 11 on the sub pixels 101 is included in the sub pixels 101. An inner surface of the groove 11 is covered with a first reflective electrode 12 and a second reflective electrode 13 which are insulated from each other. Specifically, a gap is formed between the first reflective electrode 12 and the second reflective electrode 13. With the gap, the first reflective electrode 12 and the second reflective electrode 13 are insulated from each other. Preferably, the gap is formed at a bottom of the groove 11. One of the micro light emitting diodes 15 is arranged in one of the grooves 11. One pin of the micro light emitting diode 15 is connected with the first reflective electrode 12 and the other pin of the micro light emitting diode 15 is connected with the second reflective electrode 13.

Specifically, the substrate 10 is a flexible substrate or a rigid substrate. Preferably, the substrate 10 is a glass substrate. A drive circuit (not shown in figure) is formed on the substrate 10. The drive circuit is electrically connected with the micro light emitting diode 15 via the first reflective electrode 12 and the second reflective electrode 13, and the drive circuit is used to control the micro light emitting diode 15 to emit light. The light of the micro light emitting diode 15, which irradiates at the first reflective electrode 12 and the second reflective electrode 13 will be reflected back to the groove 11 by the first reflective electrode 12 and the second reflective electrode 13.

Furthermore and specifically, the first reflective electrode 12 and the second reflective electrode 13 can be manufactured with a highly reflective metal material. For instance, it can be made of aluminum or silver.

In the present invention, by arranging the groove 11 on the substrate 10 and covering the inner surface of the groove 11 with the reflective electrode (the first reflective electrode 12 and the second reflective electrode 13), and by connecting the drive circuit and the micro light emitting diode 15 with reflective electrodes, the drive circuit on the substrate 10 controls the micro light emitting diode 15 to emit light. The light emitted from the micro light emitting diode 15 can be reflected back to the groove 11 with the reflective electrodes of the inner surface of the groove 11, and thereby, to reduce the loss of light energy and to improve light utilization.

Furthermore, the micro light emitting diode display panel further comprises a reflective layer 16. The reflective layer 16 is located under the groove 11, and the reflective layer 16 is right opposite to a bottom of the groove 11. It can be understood that the reflective layer 16, and the first reflective electrode 12 and the second reflective electrode 13 are in the different layers. When the light emitted from the micro light emitting diode 15 is incident into the bottom of the groove 11, the light incident into the bottom of the groove 11 is reflected back to the groove 11 by the reflective layer 16. It reduces the loss of light energy and improves light utilization in advance. Furthermore, the material of the reflective layer 16 can be manufactured with a highly reflective metal material. For instance, it can be made of aluminum or silver.

Specifically, the plurality of micro light emitting diodes 15 comprise: red micro light emitting diodes, green micro light emitting diodes and blue micro light emitting diodes. Specifically, one red micro light emitting diode, one green micro light emitting diode and one blue micro light emitting diode construct one display pixel. Namely, three sub pixel regions 101 form one pixel region.

Preferably, all of the plurality of micro light emitting diodes 15 are gallium nitride (GaN) micro light emitting diodes, indium gallium nitride (InGaN) micro light emitting diodes or aluminum gallium phosphide (AlGaInP) micro light emitting diodes.

Specifically, for the plurality of micro light emitting diodes 15 on the same straight line, the common cathode structure with separated anodes can be used. Certainly, in other embodiments, the series connection of the plurality of micro light emitting diodes 15 can be used, i.e. the cathode of the previous micro light emitting diode 15 is connected with the anode of the next micro light emitting diode 15.No restriction is claimed here.

Please refer to FIG. 2. FIG. 2 is a structure diagram of a micro light emitting diode display panel according to another embodiment of the present invention. The difference of this embodiment of the previous embodiment is that a boss 14 is arranged at a bottom of the groove 11 on the substrate 10 of the micro light emitting diode display panel 100′ provided by this embodiment. With the boss 14, the first reflective electrode 12 and the second reflective electrode 13 are separated, and thus to realize the insulation of the first reflective electrode 12 and the second reflective electrode 13. Specifically, the micro light emitting diode 15 is located on the boss 14, and the two pins of the micro light emitting diode are respectively located at two sides of the boss 14.

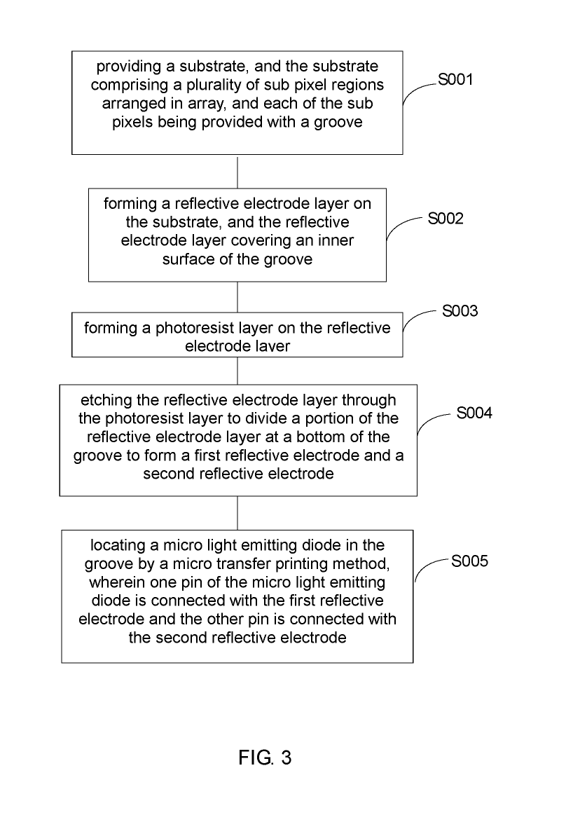

The present invention further provides a manufacturing method of the aforesaid micro light emitting diode display panel. Specifically, refer to FIG. 3. FIG. 3 is a flowchart diagram of a manufacturing method of a micro light emitting diode display panel according to the present invention. The manufacturing method of the present invention mainly comprises steps of:

step S001: providing a substrate, and the substrate comprising a plurality of sub pixel regions arranged in array, and each of the sub pixels being provided with a groove.

Specifically, refer to FIG. 1, together. The substrate 10 comprises a plurality of sub pixel regions arranged in array, and generally, each pixel region comprises three sub pixel regions 101. Each of the sub pixels 101 provided with a groove 11, and a projection of the groove 11 on the sub pixels 101 is included in the sub pixels 101. Furthermore and specifically, a method of using the mask and the photoresist etching can be used to form the groove 11 on the substrate 10.

step S002: forming a reflective electrode layer on the substrate, and the reflective electrode layer covering an inner surface of the groove.

Specifically, in one embodiment of the present invention, a sputtering method or a heat evaporation method can be used to form the reflective electrode layer on the substrate 10. Specifically, the reflective electrode layer covers an inner surface of the groove 11. The material of the reflective electrode layer can be manufactured with a highly reflective metal material. For instance, it can be made of aluminum or silver.

In one possible embodiment of the present invention, the reflective electrode layer may also be formed by the following steps:

polydiallyldimethylammonium chloride (PDDA) of cationic polyelectrolyte state is coated on an surface of the substrate 10; preferably, the concentration of the polydiallyldimethylammonium chloride can be 2 mg/mL, and after drying with the air knife, negatively charged silver nanoparticles are coated on the polydiallyldimethylammonium chloride, and similarly, by drying with the air knife to form an Ag nanoparticles thin film, the reflective electrode layer is formed, and with the special optical property of the metal, the film layer can refocus the light emitted by the micro light emitting diode 15 to the periphery of the groove 11 to the exiting direction after refraction and reflection to reduce the light loss and to promote the light utilization.

step S003: forming a photoresist layer on the reflective electrode layer.

step S004: etching the reflective electrode layer through the photoresist layer to divide a portion of the reflective electrode layer at a bottom of the groove to form a first reflective electrode and a second reflective electrode.

Specifically, the dry etching method can be used to etch the photoresist layer and the reflective electrode layer to divide the portion of the reflective electrode layer at the bottom of the groove 11 to form the first reflective electrode 12 and the second reflective electrode 13.

It can be understood that a circuit pattern (i.e. the drive circuit) is further formed on the substrate 10 for connecting with the first reflective electrode 12 and the second reflective electrode 13 of the reflective electrode layer. The drive circuit drives the plurality of micro light emitting diodes 15 to emit light.

step S005: locating a micro light emitting diode in the groove by a micro transfer printing method, wherein one pin of the micro light emitting diode is connected with the first reflective electrode and the other pin is connected with the second reflective electrode.

The plurality of micro light emitting diodes 15 can be manufactured by the micro transfer printing method. The specific operation process is: first, providing an original substrate, and producing the plurality of micro light emitting diodes 15 on the original substrate, and then, transfer printing the plurality of micro light emitting diodes 15 into the grooves 11 on the substrate 10 with a micro transfer printing head.

In the manufacturing method of the micro light emitting diode display panel of this embodiment, by arranging the groove on the substrate and covering the inner surface of the groove with the reflective electrode, and by connecting the reflective electrodes with the micro light emitting diode, the drive circuit on the substrate controls the micro light emitting diode to emit light. The light emitted from the micro light emitting diode can be reflected back to the groove with the reflective electrodes of the inner surface of the groove, and thereby, to reduce the loss of light energy and to improve light utilization.

In the description of the present specification, the reference terms, “one embodiment”, “some embodiments”, “an illustrative embodiment”, “an example”, “a specific example”, or “some examples” mean that such description combined with the specific features of the described embodiments or examples, structure, material, or characteristic is included in the utility model of at least one embodiment or example. In the present specification, the terms of the above schematic representation do not certainly refer to the same embodiment or example. Meanwhile, the particular features, structures, materials, or characteristics which are described may be combined in a suitable manner in any one or more embodiments or examples.

Above are embodiments of the present invention, which does not limit the scope of the present invention. Any modifications, equivalent replacements or improvements within the spirit and principles of the embodiment described above should be covered by the protected scope of the invention.

What is claimed is:

1. A micro light emitting diode display panel, comprising a substrate and a plurality of micro light emitting diodes, and the substrate comprising a plurality of sub pixel regions arranged in array, and each of the sub pixels being provided with a groove, and an inner surface of the groove being covered with a first reflective electrode and a second reflective electrode which are insulated from each other, and each of the micro light emitting diodes being arranged in one of the grooves, and one pin of the micro light emitting diode being connected with the first reflective electrode and the other pin being connected with the second reflective electrode, and the first reflective electrode and the second reflective electrode reflect light emitted from the micro light emitting diode back to the groove.

2. The micro light emitting diode display panel according to claim 1, further comprising a reflective layer, and the reflective layer being located under the groove, and the reflective layer reflecting the light emitted from the micro light emitting diode back to the groove.

3. The micro light emitting diode display panel according to claim 1, wherein a boss is arranged at a bottom of the groove, and the boss separates the first reflective electrode and the second reflective electrode.

4. The micro light emitting diode display panel according to claim 3, wherein the micro light emitting diode is located on the boss, and the two pins of the micro light emitting diode are respectively located at two sides of the boss.

5. The micro light emitting diode display panel according to claim 1, wherein a material of the first reflective electrode and the second reflective electrode is aluminum or silver.

6. The micro light emitting diode display panel according to claim 1, wherein the plurality of micro light emitting diodes comprise red micro light emitting diodes, green micro light emitting diodes and blue micro light emitting diodes.

7. The micro light emitting diode display panel according to claim 1, wherein all of the plurality of micro light emitting diodes are GaN micro light emitting diodes, InGaN micro light emitting diodes and AlGaInP micro light emitting diodes.

8. A manufacturing method of a micro light emitting diode display panel, comprising:
providing a substrate, and the substrate comprising a plurality of sub pixel regions arranged in array, and each of the sub pixels being provided with a groove;
forming a reflective electrode layer on the substrate, and the reflective electrode layer covering an inner surface of the groove;
forming a photoresist layer on the reflective electrode layer;
etching the reflective electrode layer through the photoresist layer to divide a portion of the reflective electrode layer at a bottom of the groove to form a first reflective electrode and a second reflective electrode;
locating a micro light emitting diode in the groove by a micro transfer printing method, wherein one pin of the micro light emitting diode is connected with the first reflective electrode and the other pin is connected with the second reflective electrode.

9. The manufacturing method of the micro light emitting diode display panel according to claim 8, wherein a sputtering method or a heat evaporation method is used to form the reflective electrode layer on the substrate.

10. The manufacturing method of the micro light emitting diode display panel according to claim 8, wherein the step of forming the reflective electrode layer on the substrate, and the reflective electrode layer covering the inner surface of the groove comprises coating polydiallyldimethylammonium chloride on an surface of the substrate, and coating negatively charged silver nanoparticles to form the reflective electrode layer.
